(19) United States
(12) Patent Application Publication
(10) Pub. No.: US 2017/0156217 A1
(43) Pub. Date: Jun. 1, 2017

(54) DESMEAR TREATMENT DEVICE AND DESMEAR TREATMENT METHOD

(71) Applicant: Ushio Denki Kabushiki Kaisha, Tokyo (JP)

(72) Inventors: Hiroki HORIBE, Tokyo (JP); Tomoyuki HABU, Tokyo (JP); Shun MARUYAMA, Tokyo (JP)

(73) Assignee: Ushio Denki Kabushiki Kaisha, Tokyo (JP)

(21) Appl. No.: 15/321,163

(22) PCT Filed: Mar. 19, 2015
(86) PCT No.: PCT/JP2015/058190

§ 371 Date: Dec. 21, 2016

(30) Foreign Application Priority Data
Jun. 30, 2014 (JP) 2014-133924

(51) Int. Cl. H05K 3/26; B08B 7/00; B08B 5/00; H05K 3/00

(52) U.S. Cl. CPC H05K 3/26; H05K 3/0055; B08B 7/0057; B08B 5/00; H05K 2203/087; H05K 2203/10

(57) ABSTRACT

The present invention has as its object the provision of a desmear treatment device and a desmear treatment method capable of sufficiently removing smear remaining in a to-be-treated object in a short amount of time. The desmear treatment device of the present invention includes: a treatment chamber in which a to-be-treated object is disposed; a light source unit in which an ultraviolet lamp for irradiating the to-be-treated object with ultraviolet rays is housed; a light transmissive window that is disposed between the treatment chamber and the light source unit and that transmits the ultraviolet rays from the ultraviolet lamps; and treatment gas supply means for supplying a treatment gas containing a source of active species to the treatment chamber. The treatment gas supply means includes a treatment gas supply source and a control unit for controlling a supplied amount of the treatment gas from the treatment gas supply source. The control unit has a function of controlling the treatment gas from the treatment gas supply source to be supplied as a purge gas when irradiating the to-be-treated object with ultraviolet rays.

### TECHNICAL FIELD

The present invention relates to a desmear treatment device and a desmear treatment method for removing smear remaining in a wiring board material in a manufacturing process of a wiring board.

### BACKGROUND ART

A multilayer wiring board in which insulating layers and conductive layers (wiring layers) are layered in an alternate manner has been known as an example of a wiring board for mounting a semiconductor element such as a semiconductor integrated circuit element. In such a multilayer wiring board, a via hole or a through-hole passing through one or more insulating layers in a thickness direction thereof is formed to electrically connect one conductive layer to another conductive layer.

FIG. 4 is an explanatory diagram illustrating an example of a manufacturing process of a multilayer wiring board. In the manufacturing process of the multilayer wiring board, a conductive layer 3 with a required pattern is first formed on a surface of a first insulating layer 2 as illustrated in FIG. 4(a). Next, a second insulating layer 4 is formed on the surface of the first insulating layer 2 including the conductive layer 3 as illustrated in FIG. 4(b). Thereafter, a through-hole 5, extending to pass through the second insulating layer 4 in a thickness direction thereof, is formed in a required part of the second insulating layer 4 as illustrated in FIG. 4(c) by drill machining or laser machining.

When forming the through-hole 5 in the second insulating layer 4, smear 6, derived from the material that forms the second insulating layer, remains on an inner wall surface of the through-hole 5 in the second insulating layer 4, a region around the through-hole 5 on a surface of the second insulating layer 4, and a bottom of the through-hole 5, i.e., part of the conductive layer 3 exposed by the through-hole 5, for example. Thus, a desmear treatment for removing the smear is performed on the resultant wiring board material.

As an example of desmear treatment methods for wiring board materials, a wet method for removing smear remaining in a wiring board material by immersing the wiring board material into an alkaline solution, which is prepared by dissolving potassium permanganate or sodium hydroxide, to dissolve or peel off the smear (See Patent Literature 1.) has been known in the conventional techniques.

The desmear treatment by the wet method, however, has a problem of a considerably high desmear treatment cost due to taking a long time for the smear to be dissolved in the alkaline solution, the need to clean and neutralize the wiring board material after being immersed into the alkaline solution, the need to perform liquid waste disposal of the used alkaline solution, etc.

For such a reason, methods (hereinafter, these are referred to as “dry methods” since no liquid is used in contrast to the conventional wet methods) in which devices (see Patent Literatures 2 and 3) for decomposing and removing an organic substance with active species produced by irradiating a wiring board material with ultraviolet rays in the presence of a treatment gas containing a source of active species are applied to desmear treatments have been under study.

In a desmear treatment according to such a dry method, a wiring board material as a to-be-treated object is disposed so as to face a light transmissive window that transmits ultraviolet rays. Thereafter, the to-be-treated object is irradiated with ultraviolet rays via the light transmissive window while causing a treatment gas containing active species to flow between the to-be-treated object and the light transmissive window. This causes the source of active species in the treatment gas to be decomposed and excited to produce active species. Smear remaining in the to-be-treated object then reacts with the active species to decompose the smear and thus produce a decomposed gas such as CO₂. In this manner, the smear remaining in the wiring board material is removed.

### CITATION LIST

### Patent Literature

Patent Literature 1: Japanese Patent Application Laid-Open No. 2010-205801

Patent Literature 2: Japanese Patent Application Laid-Open No. 2007-227496

Patent Literature 3: Japanese Patent Application Laid-Open No. Hei. 08-180757

### SUMMARY OF INVENTION

### Technical Problem

In order to sufficiently remove the smear remaining in the wiring board material as the to-be-treated object in the desmear treatment according to the dry method, it is effective to irradiate the wiring board material with ultraviolet rays for a longtime. When the wiring board material is irradiated with ultraviolet rays for a long time, however, a problem arises in that an insulating layer itself, which constitutes the wiring board material, is decomposed.

As means for reliably performing a desmear treatment in a short amount of time, it is considered that a distance between the light transmissive window and the to-be-treated object is reduced and means for supplying a treatment gas having a source of active species at a high concentration between the light transmissive window and the to-be-treated object is provided.

However, it has been found out that such a method has the following problems.

The treatment gas is supplied so as to flow along one direction between the light transmissive window and the to-be-treated object. At this time, oxygen radicals, for example, produced by the irradiation of ultraviolet rays and a decomposed gas, such as CO₂, produced by the asking of the to-be-treated object also flow along the one direction in the gap between the light transmissive window and the to-be-treated object.

If the supplied amount of the treatment gas is large, the produced oxygen radicals, for example, immediately move to the downstream of the region between the light transmissive window and the to-be-treated object. This lowers the concentration of oxygen radicals between the light transmissive window and the to-be-treated object, thus making it difficult to perform the desmear treatment sufficiently.

If the supplied amount of the treatment gas is small, the decomposed gas, which has been produced by the decomposition of the smear, does not immediately move to the downstream of the region between the light transmissive window and the to-be-treated object. This increases the concentration of the decomposed gas between the light transmissive window and the to-be-treated object. Thus, the concentration of oxygen between the light transmissive window and the to-be-treated object becomes lower relatively. Accordingly, a sufficient amount of oxygen radicals, for example, fails to be produced, thus making it difficult to perform the desmear treatment sufficiently.

In view of this, the present invention has as its object the provision of a desmear treatment device and a desmear treatment method capable of sufficiently removing smear remaining in a to-be-treated object in a short amount of time.

### Solution to Problem

According to the present invention, there is provided a desmear treatment device including: a treatment chamber in which a to-be-treated object is disposed; a light source unit in which an ultraviolet lamp for irradiating the to-be-treated object with ultraviolet rays is housed; a light transmissive window that is disposed between the treatment chamber and the light source unit and that transmits the ultraviolet rays from the ultraviolet lamp; and treatment gas supply means for supplying a treatment gas containing a source of active species to the treatment chamber, wherein

the treatment gas supply means includes a treatment gas supply source and a control unit for controlling a supplied amount of the treatment gas from the treatment gas supply source, and

the control unit has a function of controlling the treatment gas from the treatment gas supply source to be supplied as a purge gas when irradiating the to-be-treated object with ultraviolet rays.

According to the present invention, there is provided a desmear treatment method for removing smear remaining in a to-be-treated object by irradiating the to-be-treated object with ultraviolet rays via a light transmissive window that transmits ultraviolet rays in the presence of a treatment gas containing a source of active species,

the method including repeating a treatment process including a reaction step of causing a reaction between active species produced by irradiating the treatment gas supplied between the to-be-treated object and the light transmissive window with ultraviolet rays and the smear and a purging step of supplying a purge gas that is the treatment gas between the to-be-treated object and the light transmissive window.

In the desmear treatment method of the present invention, a supplied amount of the purge gas in the purging step may preferably be larger than a supplied amount of the treatment gas in the reaction step.

Moreover, a supplied amount of the treatment gas in the reaction step may preferably be 0.

Moreover, a duration of the reaction step may preferably be 5 to 15 seconds.

Moreover, the number of the treatment processes may preferably be 5 to 15.

Moreover, the source of active species may preferably be an oxygen gas or a mixture of an oxygen gas and ozone.

Moreover, the to-be-treated object may preferably be irradiated with ultraviolet rays via the light transmissive window in the purging step.

### Advantageous Effects of Invention

According to the present invention, the smear remaining in the to-be-treated object can be sufficiently removed in a short amount of time by repeating the treatment process including the reaction step in which the to-be-treated object is irradiated with ultraviolet rays in the presence of the treatment gas and the purging step in which the purge gas that is the treatment gas is supplied.

### BRIEF DESCRIPTION OF DRAWINGS

FIG. 1 is an explanatory sectional view illustrating the construction of an exemplary desmear treatment device of the present invention.

FIG. 2 is an explanatory diagram illustrating operating states of ultraviolet lamps and treatment gas supply means in the desmear treatment device of the present invention.

FIG. 3 is an explanatory diagram illustrating states in a treatment chamber during operations of the desmear treatment device of the present invention.

FIG. 4 is an explanatory diagram illustrating an example of a manufacturing process of a multilayer wiring board.

### DESCRIPTION OF EMBODIMENTS

An embodiment of the present invention will be described below in detail.

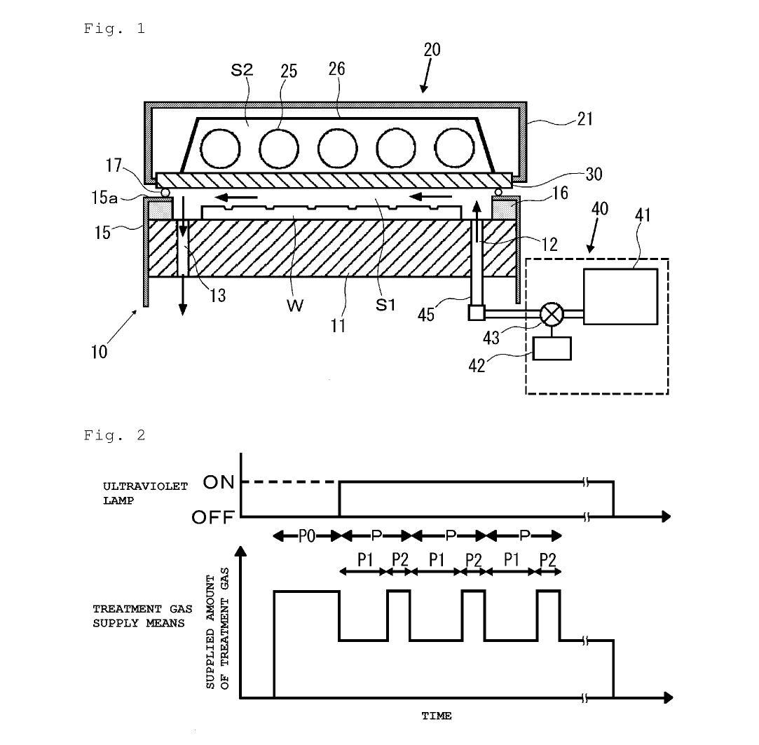

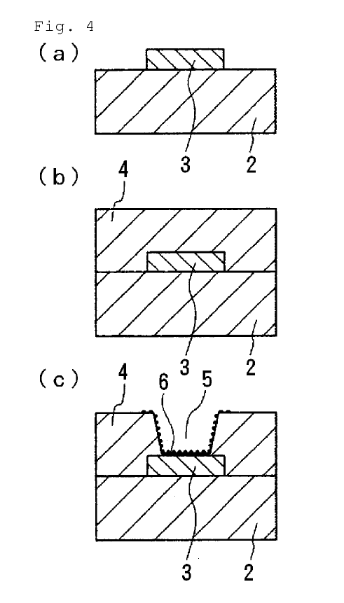

FIG. 1 is an explanatory sectional view illustrating the construction of an exemplary desmear treatment device of the present invention. The desmear treatment device includes: a treatment chamber forming member 10 that forms a treatment chamber S1 in which a desmear treatment is performed on a to-be-treated object W; and a light source unit 20 provided above the treatment chamber forming member 10. The to-be-treated object W, which is an object to be treated by the desmear treatment device of the present invention, is a wiring board material in the shape of a generally flat plate, for example, provided with a hole, such as a via hole or a through-hole, extending in a thickness direction thereof (See FIG. 4(c).).

The treatment chamber forming member 10 has a housing 15 in the shape of a rectangular cylinder. A rectangular plate-shaped placement stage 11 on which the to-be-treated object W is placed is provided in the housing 15. A rectangular frame-shaped spacer member 16 is disposed on a surface of the placement stage 11 along a periphery thereof. In the illustrated example, an upper end portion 15a of the housing 15 is formed so as to project inwardly to cover an upper surface of the spacer member 16. The light source unit 20 is disposed on the upper end portion 15a of the housing 15 in the treatment chamber forming member 10 via a sealing member 17. Thus, the treatment chamber S1 in which the desmear treatment is performed on the to-be-treated object W is formed between the placement stage 11 and the light source unit 20.

The light source unit 20 includes a casing 21 in the shape of a generally rectangular parallelepiped box with an opening on a lower side thereof. The opening of the casing 21 is airtightly provided with a light transmissive window 30 that transmits vacuum ultraviolet rays. A hermetically sealed lamp housing chamber S2 is formed in the casing 21.

In the lamp housing chamber S2, a plurality of rod-shaped ultraviolet lamps 25 are disposed side by side so as to be parallel to one another in the same horizontal plane. A reflecting mirror 26 is provided above the ultraviolet lamps 25 in the lamp housing chamber S2. Moreover, the casing 21 is provided with gas purging means (not shown) for purging the inside of the lamp housing chamber S2 with an inert gas such as a nitrogen gas.

A preferably used ultraviolet lamp 25 is an ultraviolet lamp that emits vacuum ultraviolet rays capable of exciting a source of active species. Publicly known various lamps may be used as the ultraviolet lamp 25 that emits vacuum ultraviolet rays. Specifically, as an example of the ultraviolet lamp 25, may be mentioned a low-pressure mercury lamp that emits vacuum ultraviolet rays of 185 nm, a xenon excimer lamp that emits vacuum ultraviolet rays with a center wavelength of 172 nm or a fluorescent excimer lamp in which a xenon gas is sealed in a luminous tube and a phosphor that emits vacuum ultraviolet rays of 190 nm, for example, is applied onto an inner surface of the luminous tube. Among these, the xenon excimer lamp is preferably used.

Any material having a transmissive property for vacuum ultraviolet rays emitted from the ultraviolet lamps 25 and having resistance properties against vacuum ultraviolet rays and produced active species may be used as a material for forming the light transmissive window 30. Synthetic quartz glass, for example, may be used as such a material.

The placement stage 11 is provided with a gas supply hole 12 and a gas discharge hole 13, each passing through the placement stage 11 in a thickness direction thereof. An opening of each of the gas supply hole 12 and the gas discharge hole 13 has the shape of a strip extending along a lamp axis direction of the ultraviolet lamp 25. The gas supply hole 12 and the gas discharge hole 13 are formed at positions spaced apart from each other in a direction along which the ultraviolet lamps 25 are arranged. Here, the to-be-treated object W is disposed on the surface of the placement stage 11 at a position between the gas supply hole 12 and the gas discharge hole 13 in the direction along which the ultraviolet lamps 25 are arranged.

A total opening area of the gas discharge hole 13 is preferably larger than a total opening area of the gas supply hole 12. Forming the gas discharge hole 13 having the total opening area larger than that of the gas supply hole 12 allows a gas to flow uniformly in one direction from the gas supply hole 12 toward the gas discharge hole 13 without the stagnation of the gas in the treatment chamber S1. Thus, stable gas flow can be maintained in the treatment chamber S1.

The dimensions of the openings of the gas supply hole 12 and the gas discharge hole 13 are appropriately designed in accordance with the dimensions of the to-be-treated object W. As an example of the dimensions of the openings of the gas supply hole 12 and the gas discharge hole 13, the dimensions of the opening of the gas supply hole 12 are 3 mm×600 mm, for example, and the dimensions of the opening of the gas discharge hole 13 are 10 mm×600 mm, for example, when the planar dimensions of the to-be-treated object W are 500 mm×500 mm.

Treatment gas supply means 40 for supplying a treatment gas to the treatment chamber S1 is connected to the gas supply hole 12 via a gas pipe 45. The treatment gas supply means 40 is composed of a treatment gas supply source 41 in which the treatment gas is retained and a control unit 42 for controlling a supplied amount of the treatment gas from the treatment gas supply source 41 by an adjustment of a valve 43 provided in the gas pipe 45. The control unit 42 in the treatment gas supply means 40 has a function of controlling the treatment gas from the treatment gas supply source 41 to be supplied as a purge gas when irradiating the to-be-treated object W with vacuum ultraviolet rays.

A treatment gas containing a source of active species is used as the treatment gas supplied from the treatment gas supply means 40. Any source capable of producing active species by being irradiated with vacuum ultraviolet rays can be used as the source of active species contained in the treatment gas. As specific examples of such a source of active species, may be mentioned a source for producing oxygen radicals such as an oxygen gas (O₂) or ozone (O₃), a source for producing OH radicals such as water vapor, a source for producing fluorine radicals such as carbon tetrafluoride (CF₄), a source for producing chlorine radicals such as a chlorine gas (Cl₂) and a source for producing bromine radicals such as hydrogen bromide (HBr). Among these, the source for producing oxygen radicals is preferably used. An oxygen gas (O₂) or a mixture of an oxygen gas (O₂) and ozone (O₃), in particular, is preferably used.

A concentration of the source of active species in the treatment gas is preferably not lower than 50% by volume, more preferably not lower than 70% by volume, and further preferably not lower than 90% by volume. The use of such a treatment gas produces a sufficient amount of active species when the treatment gas receives vacuum ultraviolet rays, thus allowing for reliable accomplishment of the desired desmear treatment.

When a treatment gas containing at least ozone (O₃) as the source of active species is used, a concentration of ozone (O₃) in the treatment gas is preferably 0.1 to 12% by volume, more preferably 1 to 12% by volume.

Moreover, the placement stage 11 is preferably provided with heating means (not shown) for heating the to-be-treated object W. Such a construction can promote an action by the active species along with an increase in the temperature of a to-be-treated surface of the to-be-treated object W. Thus, the desmear treatment can be performed efficiently on the to-be-treated object W. Moreover, by causing the treatment gas to flow through the gas supply hole 12, the heated treatment gas can be supplied into the treatment chamber S1. Thus, the treatment gas flowing along the to-be-treated surface of the to-be-treated object W can contribute to an increase in the temperature of the to-be-treated surface of the to-be-treated object W. Consequently, the above-described effect can be obtained more reliably.

As heating conditions by the heating means, the temperature of the to-be-treated surface of the to-be-treated object W is preferably not lower than 80° C. and not more than 340° C., for example, more preferably not lower than 80° C. and not more than 200° C.

According to a desmear treatment method of the present invention, a desmear treatment is performed on the to-be-treated object W as follows with the above desmear treatment device.

First, the to-be-treated object W is placed at a position between the gas supply hole 12 and the gas discharge hole 13 on the surface of the placement stage 11 with the light source unit 20 being detached from the treatment chamber forming member 10. Next, the light source unit 20 is disposed on the treatment chamber forming member 10 via the sealing member 17. Thus, the light transmissive window 30 in the light source unit 20 is disposed so as to face the to-be-treated surface of the to-be-treated object W via a gap therebetween. The to-be-treated object W is heated via the placement stage 11 by the heating means as needed.

A distance between the light transmissive window 30 and the to-be-treated object W in the above-described construction is preferably not more than 1 mm, more preferably 0.1 to 0.7 mm. If the distance exceeds 1 mm, large part of vacuum ultraviolet rays is absorbed by the treatment gas before the vacuum ultraviolet rays reach the to-be-treated object W from the light transmissive window 30, in a reaction step to be described later. This lowers an amount of active species produced in the vicinity of the surface of the to-be-treated object W and thus lowers the concentration of the active species in the vicinity of the surface of the to-be-treated object W. Moreover, since the decomposition speed of smear, which is present on the surface of the to-be-treated object W, by vacuum ultraviolet rays is lowered, the treatment capability is lowered.

According to the present invention, a pretreatment process in which the inside of the treatment chamber S1 is purged by the purge gas that is the treatment gas is performed and then a treatment process including the reaction step and a purging step is repeated.

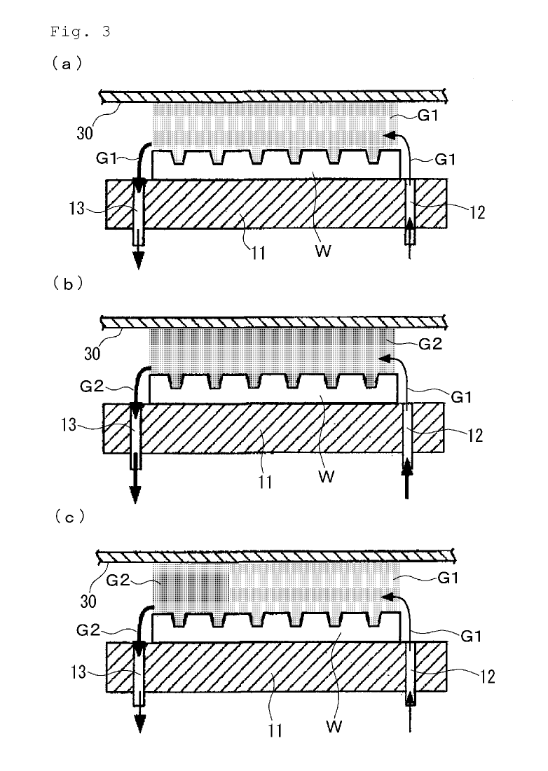

FIG. 2 is an explanatory diagram illustrating operating states of the ultraviolet lamps 25 and the treatment gas supply means 40 in the desmear treatment device of the present invention. With reference to FIG. 2, the desmear treatment method of the present invention will be described below.

In a pretreatment process P0, a treatment gas G1 is supplied, as a purge gas, into the treatment chamber S1 from the gas supply hole 12 by the treatment gas supply means 40 as illustrated in FIG. 3(a) while the operation of the ultraviolet lamps 25 is stopped (while the ultraviolet lamps 25 are turned off). The treatment gas G1 supplied from the gas supply hole 12 flows toward the gas discharge hole 13 between the light transmissive window 30 and the to-be-treated object W. Thereafter, the treatment gas G1 is discharged from the gas discharge hole 13 to the outside. In this manner, the inside of the treatment chamber S1 is purged by the treatment gas G1. It is only necessary that 90% or more, for example, of the gas inside the treatment chamber S1 has been replaced by the treatment gas G1 by the completion of the pretreatment process.

A supplied amount and a supply duration of the treatment gas G1 in the pretreatment process P0 are not limited to any particular values. The supplied amount and the supply duration can be set appropriately in accordance with the dimensions of the to-be-treated object W and the dimensions of the treatment chamber S1, for example. When the dimensions of the to-be-treated object W are 500 mm×500 mm, for example, the supplied amount of the treatment gas G1 is 0.1 to 10 L/min and the supply duration is 0.1 to 10 seconds.

A treatment process P includes: a reaction step P1 in which the to-be-treated object W is irradiated with ultraviolet rays via the light transmissive window 30 in the presence of the treatment gas G1 supplied between the to-be-treated object W and the light transmissive window 30 to cause a reaction between the produced active species and the smear remaining in the to-be-treated object W; and a purging step P2 in which the purge gas that is the treatment gas G1 is supplied between the to-be-treated object W and the light transmissive window 30.

In the reaction step P1, the ultraviolet lamps 25 are actuated, so that the ultraviolet lamps 25 emit vacuum ultraviolet rays. The vacuum ultraviolet rays are irradiated, via the light transmissive window 30, onto the to-be-treated object W as well as the treatment gas G1 present between the light transmissive window 30 and the to-be-treated object W. Consequently, the source of active species contained in the treatment gas G1 is decomposed to produce the active species. As a result, the smear remaining in the to-be-treated object W and the active species react to decompose the smear and thus produce a decomposed gas such as CO₂. Thus, a posttreatment gas G2 in which the treatment gas and the decomposed gas are mixed is produced between the light transmissive window 30 and the to-be-treated object W as illustrated in FIG. 3(b).

In such a reaction step P1, a supplied amount of the treatment gas G1 is not more than 0.1 L/min, for example, preferably 0 L/min. Satisfying such a condition allows the produced active species to stay between the light transmissive window 30 and the to-be-treated object W. Thus, the reaction between the active species and the smear proceeds with high efficiency, thereby allowing for the removal of the smear in a short amount of time. If the supplied amount of the treatment gas G1 in the reaction step is excessively large, the produced active species immediately move to the downstream of the region between the light transmissive window 30 and the to-be-treated object W. This lowers the concentration of the active species between the light transmissive window 30 and the to-be-treated object W, resulting in a risk of deterioration in smear removal efficiency.

A duration of the reaction step P1 is preferably 5 to 15 seconds. If the duration of the reaction step P1 is less than 5 seconds, the process transitions to the purging step P2 before the reaction between the produced active species and the smear sufficiently proceeds. Thus, there is a risk of deterioration in smear removal efficiency. If the duration of the reaction step P1 exceeds 15 seconds, on the other hand, the active species produced by the treatment gas supplied in the purging step P2 are all consumed for the reaction. Thus, the reaction between the smear and the active species cannot proceed further, resulting in a risk of deterioration in smear removal efficiency.

In the purging step P2, the treatment gas G1 is supplied, as a purge gas, to the treatment chamber S1 from the gas supply hole 12 by the treatment gas supply means 40. The treatment gas G1 supplied from the gas supply hole 12 flows toward the gas discharge hole 13 between the light transmissive window 30 and the to-be-treated object W. This causes the posttreatment gas G2 between the light transmissive window 30 and the to-be-treated object W to be moved toward the gas discharge hole 13, as illustrated in FIG. 3(c), and discharged from the gas discharge hole 13 to the outside. In this manner, the inside of the treatment chamber S1 is purged by the treatment gas G1. It is only necessary that 90% or more, for example, of the gas inside the treatment chamber S1 has been replaced by the treatment gas G1 by the completion of the purging step P2.

In such a purging step P2, the supplied amount of the treatment gas (purge gas) G1 is preferably larger than the supplied amount of the treatment gas G1 in the reaction step. Specifically, the supplied amount of the treatment gas G1 in the purging step P2 is preferably 0.1 to 10 L/min. If the supplied amount of the treatment gas G1 in the purging step P2 is excessively small, the posttreatment gas G2 remains in the treatment chamber S1, failing to be sufficiently replaced by the treatment gas G1. Thus, there is a risk of having difficulty in sufficiently supplying active species required in the reaction step P1. If the supplied amount of the treatment gas G1 in the purging step P2 is excessively large, on the other hand, it may seem efficient since the purging step P2 can be shortened to an appropriate amount of time. However, this may cause an undesired turbulent flow or the like, and thus the purging of the posttreatment gas G2 cannot be sufficiently performed in an efficient manner.

Moreover, the duration of the purging step P2 is preferably shorter than the duration of the reaction step P1. Specifically, the duration of the purging step P2 is preferably 10 to 15 seconds.

Although the operation of the ultraviolet lamps 25 may be stopped, i.e., irradiating the to-be-treated object W with ultraviolet rays may be stopped in the purging step P2, the purging step P2 is preferably performed while irradiating the to-be-treated object W with ultraviolet rays via the light transmissive window 30 as illustrated in FIG. 2.

The desmear treatment of the to-be-treated object can be achieved by repeating such a treatment process P including the reaction step P1 and the purging step P2.

The number of the treatment processes P in the above-described construction is preferably 5 to 15. If the number of the treatment processes P is less than 5, it may be difficult to remove the smear remaining in the to-be-treated object W sufficiently. If the number of the treatment processes P is more than 15, on the other hand, there is a risk of decomposing the insulating layer itself in the wiring board material as the to-be-treated object W.

According to the present invention, the smear remaining in the to-be-treated object W can be sufficiently removed in a short amount of time by repeating the treatment process P including the reaction step P1 in which the to-be-treated object W is irradiated with ultraviolet rays in the presence of the treatment gas G1 and the purging step P2 in which the purge gas that is the treatment gas G1 is supplied.

### EXAMPLES

### Example 1

With reference to the construction illustrated in FIG. 1, a desmear treatment device was manufactured. Specifications of this desmear treatment device are as follows.

### Placement Stage:

Dimensions: 650 mm×650 mm×20 mm
Material: aluminum
Opening dimensions of gas supply hole: 3 mm×600 mm
Opening dimensions of gas discharge hole: 10 mm×600 mm
Distance between gas supply hole and gas discharge hole: 510 mm

### Ultraviolet Lamps:

Type: xenon excimer lamp
Emission length: 700 mm
Diameter: 40 mm
Number of ultraviolet lamps: 5
Arrangement pitch of ultraviolet lamps (distance between central axes of adjacent ultraviolet lamps): 60 mm
Rated input power: 500 W

### Light Transmissive Window:

Dimensions: 550 mm×550 mm×5 mm
Material: synthetic quartz glass

### Lamp Housing Chamber:

Type of purge gas: nitrogen gas
Flow rate of purge gas: 100 L/min

### Treatment Chamber:

Dimensions: 600 mm×600 mm×1 mm

### Treatment Gas:

Oxygen gas (concentration of 100%)

With the above-described desmear device, a desmear treatment was performed on the following to-be-treated object under the following conditions.

### To-Be-Treated Object:

Configuration: a wiring board material in which an insulating layer with a via hole is layered on copper foil
Planar dimensions: 500 mm×500 mm
Thickness of copper foil: 35 μm
Thickness of insulating layer: 30 μm
Diameter of via hole: 50 μm

### Conditions of Desmear Treatment:

Distance between light transmissive window and to-be-treated object: 0.3 mm

Temperature of placement stage: 120° C.

Supplied amount of treatment gas in pretreatment process: 10 L/min

Supply duration of treatment gas in pretreatment process: 0.1 second

Supplied amount of treatment gas in reaction step: 0 L/min

Duration of reaction step: 10 seconds
Supplied amount of treatment gas in purging step: 10 L/min
Operating state of ultraviolet lamps in purging step: lighted
Duration of purging step: 0.1 seconds
Number of treatment processes: 5
Duration of desmear treatment ((duration of reaction step+duration of purging step)×number of treatment processes): 50.5 seconds

After the desmear treatment, the bottom (copper foil) of the via hole in the to-be-treated object was observed with a scanning electron microscope (SEM). In the SEM image, smear remaining on the bottom of the via hole appears blackish, whereas a portion where smear has been removed appears whitish. Thus, if image processing is performed to emphasize the black and white of the SEM image, a black region can be recognized as smear, whereas a white region can be recognized as a region where smear has been removed. Such a processing method is referred to as image binarization. With this technique, the degree of the remaining smear was quantified and evaluated.

More specifically, the area of the entire bottom of the via hole and the area of the white region were obtained from the SEM image, and the value of “(the area of the white region/the area of the entire bottom of the via hole)×100” was calculated and expressed as a degree of desmear completeness (%). If desmearing is completed, the entire bottom of the via hole appears white. Thus, the degree of desmear completeness is 100%. In contrast, there is no white region in a state before desmearing. Thus, the degree of desmear completeness is 0%. Note however that the completion of desmearing does not always numerically coincide with 100% due to the digital processing of the image. Thus, 90% or more is considered as the completion of desmearing. The result is shown in Table 1.

### Examples 2 and 3

A desmear treatment was performed on a to-be-treated object in the same manner as that in Example 1 except that the supplied amount of the treatment gas and the duration in the reaction step as well as the supplied amount of the treatment gas and the duration in the purging step were changed in accordance with Table 1 below. The degree of desmear completeness on the bottom of the via hole in the to-be-treated object was then measured. The results are shown in Table 1.

### Comparative Example 1

A desmear treatment was performed on a to-be-treated object in the same manner as that in Example 1 except that a treatment process including only a reaction step with a treatment gas supplied amount of 0.1 L/min and a duration of 100 seconds was performed once instead of the treatment process including the reaction step and the purging step. The degree of desmear completeness on the bottom of the via hole in the to-be-treated object was then measured. The result is shown in Table 1.

### Comparative Example 2

A desmear treatment was performed on a to-be-treated object in the same manner as that in Comparative Example 1 except that the supplied amount of the treatment gas was changed to 0.01 L/min and the duration of the reaction step was changed to 150 seconds. The degree of desmear completeness on the bottom of the via hole in the to-be-treated object was then measured. The result is shown in Table 1.

### Comparative Example 3

A desmear treatment was performed on a to-be-treated object in the same manner as that in Comparative Example 1 except that the supplied amount of the treatment gas was changed to 1 L/min and the duration of the reaction step was changed to 150 seconds. The degree of desmear completeness on the bottom of the via hole in the to-be-treated object was then measured. The result is shown in Table 1.

TABLE 1

| | REACTION STEP | | PURGING STEP | | THE NUMBER | | |
|---|---|---|---|---|---|---|---|
| | SUPPLIED | DURATION OF | SUPPLIED | DURATION OF | OF | DURATION OF | DEGREE OF |
| | AMOUNT OF | REACTION | AMOUNT OF | PURGING | TREATMENT | DESMEAR | DESMEAR |
| | TREATMENT | STEP | TREATMENT | STEP | PROCESSES | TREATMENT | COMPLETENESS |
| | GAS (L/min) | (sec) | GAS (L/min) | (sec) | (COUNT) | (sec) | (%) |
| EXAMPLE1 | 0 | 10 | 10 | 0.1 | 5 | 50.5 | 98 |
| EXAMPLE2 | 0.1 | 15 | 1 | 1 | 6 | 96 | 96 |
| EXAMPLE3 | 0 | 5 | 1 | 1 | 15 | 90 | 95 |
| COMPARATIVE | 0.1 | 100 | — | — | 1 | 100 | 95 |
| EXAMPLE1 | | | | | | | |
| COMPARATIVE | 0.01 | 150 | — | — | 1 | 150 | 54 |
| EXAMPLE2 | | | | | | | |
| COMPARATIVE | 1 | 150 | — | — | 1 | 150 | 63 |
| EXAMPLE3 | | | | | | | |

As is apparent from the results in Table 1, it was confirmed that the smear remaining in the to-be-treated object can be sufficiently removed in a short amount of time according to Examples 1 to 3.

### REFERENCE SIGNS LIST

2 first insulating layer
3 conductive layer
4 second insulating layer
5 through-hole
6 smear
10 treatment chamber forming member
11 placement stage
12 gas supply hole
13 gas discharge hole
15 housing
15a upper end portion
16 spacer member
17 sealing member
20 light source unit
21 casing
25 ultraviolet lamp
26 reflecting mirror
30 light transmissive window
40 treatment gas supply means
41 treatment gas supply source
42 control unit
43 valve
45 gas pipe
P treatment process
P0 pretreatment process
P1 reaction step
P2 purging step
G1 treatment gas
G2 posttreatment gas
S1 treatment chamber
S2 lamp housing chamber
W to-be-treated object

1. A desmear treatment method for removing smear remaining in a to-be-treated object by irradiating the to-be-treated object with ultraviolet rays via a light transmissive window that transmits ultraviolet rays in the presence of a treatment gas containing a source of active species, the method comprising:
repeating a treatment process including a reaction step of causing a reaction between active species produced by irradiating the treatment gas supplied between the to-be-treated object and the light transmissive window with ultraviolet rays and the smear and a purging step of supplying a purge gas that is the treatment gas between the to-be-treated object and the light transmissive window, wherein a supplied amount of the purge gas in the purging step is larger than a supplied amount of the treatment gas in the reaction step.

2. The desmear treatment method according to claim 1, wherein the supplied amount of the treatment gas in the reaction step is 0.

3. The desmear treatment method according to claim 1, wherein a duration of the reaction step is 5 to 15 seconds.

4. The desmear treatment method according to claim 1, wherein the number of the treatment processes is 5 to 15.

5. The desmear treatment method according to claim 1, wherein the source of active species is an oxygen gas or a mixture of an oxygen gas and ozone.

6. The desmear treatment method according to claim 1, wherein the to-be-treated object is irradiated with ultraviolet rays via the light transmissive window in the purging step.
